(19) United States
(12) Patent Application Publication
(10) Pub. No.: US 2016/0003900 A1
(43) Pub. Date: Jan. 7, 2016

(54) SELF-TEST METHODS AND SYSTEMS FOR DIGITAL CIRCUITS

(71) Applicant: TEXAS INSTRUMENTS INCORPORATED, Dallas, TX (US)

(72) Inventors: Prakash Narayanan, Bangalore (IN); Rubin Ajit Parekhji, Bangalore (IN)

(21) Appl. No.: 14/637,543

(22) Filed: Mar. 4, 2015

(30) Foreign Application Priority Data
Jul. 4, 2014 (IN) 3323/CHE/2014

(51) Int. Cl. G01R 31/3177

(52) U.S. Cl. CPC G01R 31/3177

(57) ABSTRACT

Circuits and methods for performing self-test of digital circuits are disclosed. In an embodiment, a method includes applying a set of test patterns for performing scan testing of a digital circuit to generate scan outputs from the digital circuit. The set of test patterns includes one or more sets of base test patterns already stored in a memory and one or more sets of derived test patterns temporarily generated from the one or more sets of base test patterns. The method further includes comparing the scan outputs received from the digital circuit with reference scan outputs corresponding to the digital circuit for fault detection in the digital circuit to thereby achieve a target fault coverage of the scan testing of the digital circuit. The reference scan outputs corresponding to the digital circuit are stored in the memory.

### CROSS REFERENCE TO RELATED APPLICATIONS

This application claims the benefit of provisional patent application number “3323/CHE/2014” filed on 4^{th} of July 2014 in the Indian Patent Office, incorporated herein in its entirety.

### TECHNICAL FIELD

The present disclosure generally relates to the field of self-test methods and systems for digital circuits in electronic systems.

### BACKGROUND

Electronic systems, in various forms, are being increasingly used in applications related to a wide variety of fields such as those related to automotives, healthcare, defense, satellites, networking, communication, consumer electronic and electrical applications and the like. For example, a number of Electronic Control Units (ECUs) being used in modern cars ranges from tens to hundreds. Such widespread usage of the electronic systems in a variety of fields raises new challenges in terms of meeting safety requirements.

In order to address safety considerations, the electronic systems are now equipped with self-test capabilities of digital circuits present in the electronic systems. For example, a self-test controller is provided for performing a self-test of the digital circuits present in a typical electronic system. The self-test controller is configured to generate test patterns for example, random test patterns and/or deterministic test patterns, and is configured to apply the generated test patterns to the digital circuits for performing the self-test of the digital circuits. In random test pattern generation, a set of initial patterns (or seed values) are used to generate a limited number of test patterns and these generated test patterns can be applied for the self-test of the digital circuits by performing scan testing of the digital circuits using the generated test patterns. Due to the limited number of generated test patterns, fault coverage achieved during the self-test of the digital circuits is less than the required fault coverage as per the safety requirements. Though usage of the deterministic test patterns can achieve the required fault coverage, it requires a significant amount of memory due to large test data volume needed for the application of the deterministic test patterns. Moreover, increase in the memory requirement is even more pronounced, if there is a need to test multiple digital circuits in the electronic system. In one existing technique, insertion of test points in the digital circuits (e.g., designs-under-test) can also increase the fault coverage; however, area overhead is significantly increased with the insertions of additional test points.

### SUMMARY

This Summary is provided to introduce a selection of concepts in a simplified form that are further described below in the detailed description. This Summary is not intended to identify key or essential features of the claimed subject matter, nor is it intended to be used as an aid in determining the scope of the claimed subject matter.

Various systems and methods for self-test of digital circuits are disclosed. A method includes applying a set of test patterns for scan testing of a digital circuit to generate scan outputs from the digital circuit based on the scan testing of the digital circuit. In an example, applying the set of test patterns includes applying at least one of one or more sets of base test patterns and one or more sets of derived test patterns. Applying the one or more sets of base test patterns includes accessing the one or more sets of base test patterns stored in a memory by a self-test controller. Applying the one or more sets of derived test patterns includes temporarily generating the one or more sets of derived test patterns from the one or more sets of base test patterns. The method further includes comparing the scan outputs received from the digital circuit with reference scan outputs corresponding to the digital circuit for fault detection in the digital circuit, in which the reference scan outputs corresponding to the digital circuit are already stored in the memory.

In another embodiment, a self-test system for scan testing of one or more digital circuits is disclosed. The self-test system includes a memory and a self-test controller. The memory is configured to store one or more sets of base test patterns and one or more reference scan outputs for the scan testing of the one or more digital circuits. The self-test controller is configured to apply a set of test patterns for scan testing of a digital circuit of the one or more digital circuits to generate scan outputs from the digital circuit. In an example, the set of test patterns includes at least one of one or more sets of base test patterns and one or more sets of derived test patterns. In an example, the self-test controller is configured to apply the one or more sets of base test patterns by accessing the one or more sets of base test patterns stored in the memory. In an example, the self-test controller is configured to apply the one or more sets of derived test patterns by temporarily generating the one or more sets of derived test patterns from the one or more sets of base test patterns. The self-test controller is further configured to compare the scan outputs received from the digital circuit with reference scan outputs of the one or more reference scan outputs corresponding to the digital circuit for fault detection in the digital circuit.

Other aspects and example embodiments are provided in the drawings and the detailed description that follows.

### BRIEF DESCRIPTION OF THE FIGURES

FIG. 1 is a block diagram of an electronic system, where various example embodiments of the present disclosure can be implemented;

FIG. 2 is a block diagram of an electronic system, in accordance with an example embodiment;

FIG. 3 is a block diagram of an electronic system, in accordance with another example embodiment; and

FIG. 4 illustrates a flowchart of an example method of self-test of digital circuits, in accordance with an example embodiment.

The drawings referred to in this description are not to be understood as being drawn to scale except if specifically noted, and such drawings are only for example purposes in nature.

### DETAILED DESCRIPTION

In the following detailed description, numerous specific details are set forth in order to provide a thorough understanding of the present disclosure. However, the present disclosure may be practiced without these specific details. In other instances, well-known methods, procedures, components, and circuits have not been described in detail so as to not unnecessarily obscure aspects of the exemplary embodiments presented herein. Moreover, it is noted that structures and devices are shown in block diagram form in order to avoid obscuring the disclosure.

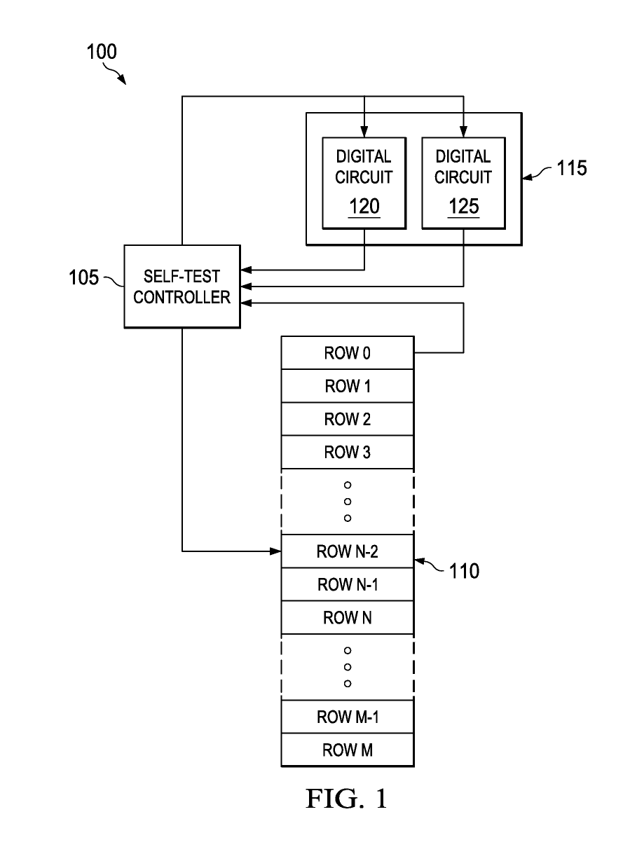

Various example embodiments of the present disclosure provide techniques for self-test of one or more digital circuits present in electronic systems for ensuring safety standards for the electronic systems, and such example embodiments of the present disclosure are presented herein with reference to FIGS. 1 to 4.

FIG. 1 is a block diagram of an electronic system 100, where various example embodiments of the present disclosure can be implemented. The electronic system 100 is configured to perform self-test of one or more digital circuits present in the electronic system 100, and the electronic system 100 can be referred to as a ‘self-test system’. The electronic system 100 includes a self-test controller 105, a memory 110, and a circuit array 115. In an example, the self-test controller 105 and the memory 110 are configured on a same chip or on different chips. The self-test controller 105 and the memory 110 along with other components are configured to perform self-test of the one or more digital circuits of the circuit array 115. The circuit array 115 includes one or more digital circuits, for example a digital circuit 120 and a digital circuit 125. Each of the digital circuits 120 and 125 can be examples of individual or multiple digital components, cores, and the like, and can be embodied on a same chip or on different chips. The electronic system 100 can include components embodied on a single chip or on multiple chips coupled to each other so as to form the self-test system. For instance, the electronic system 100 can be an example of a distributed system in an automobile where different components (e.g., the digital circuits 120 and 125) can be embodied on separate chips. As such, the electronic system 100 is shown for representative purposes only, and among the shown components, some components can be optional and/or two or more components can be embodied as a single component, or the electronic system 100 can include additional components than those shown in FIG. 1. Examples of the electronic system 100 can be electronic systems used in automobiles, medical devices, satellite systems, defense equipment, networking applications, communication applications, or any consumer electronic and electrical systems.

Without limiting to scope of the present disclosure, in an example, the self-test controller 105 is a logic built-in self-test (LBIST) controller configured on the same chip that includes the circuit array 115. In another example, the self-test controller 105 and each of the digital circuits 120 and 125 can be distributed on different chips and are communicably associated so as to perform self-test of the digital circuits 120 and 125. In an example, the self-test controller 105 can include a clock generator, a test pattern generator, and a response analyzer as known in the art. The clock generator is configured to generate a clock signal for each test cycle. The test pattern generator is configured to generate test patterns, for example deterministic test patterns for application to the digital circuits 120 and 125. The response analyzer is configured to analyze scan outputs/test response signatures received from the digital circuits 120 and 125 to determine any fault in the digital circuits 120 and 125, respectively.

The memory 110 is configured to store one or more sets of base test patterns and reference scan outputs (or one or more reference signatures) for scan testing of a digital circuit, for example the digital circuits 120 or 125. The memory 110 is also configured to store one or more sets of top-up test patterns that can be used in addition to the one or more sets of base test patterns. Examples of the memory 110 can include, but are not limited to, a program memory, a read only memory (ROM), a random access memory (RAM) and any other volatile or non-volatile memory. As illustrated in FIG. 1, the memory 110 can include a plurality of memory locations, for example from memory location 0 to memory location M (represented in form of rows). In one example, the one or more sets of base test patterns (hereinafter interchangeably referred to as ‘base test patterns’) are stored in the memory locations from locations 0 to N, where N is smaller than M, and other memory locations (e.g., M-N) can be used to store the reference scan outputs and the one or more sets of top-up test patterns (hereinafter interchangeably referred to as ‘top-up test patterns’). In an embodiment, each of the digital circuits 120 and 125 in the circuit array 115 is configured to include design for test functionality, and can include a decompressor, a plurality of scan chains and a compactor. In an example, the compactor is configured as a multiple-input signature register (MISR).

During a test cycle, the self-test controller 105 is configured to apply a set of test patterns for scan testing of a digital circuit, for example the digital circuit 120. In an example embodiment, the set of test patterns may be at least one of ‘the base test patterns’ and one or more sets of derived test patterns. It should be understood that the ‘base test patterns’ are stored in the memory 110; and the one or more sets of derived test patterns (hereinafter interchangeably referred to as ‘derived test patterns’) are temporarily generated from the ‘base test patterns’ for performing the scan test of the digital circuit 120. Herein, in an example, ‘temporary generation’ of the ‘derived test patterns’ refers to generating the ‘derived test patterns’ only for applying the generated ‘derived test patterns’ for the scan testing of the digital circuit 120, and the generated ‘derived test patterns’ may not be stored in any memory. It should be appreciated that one of the objectives of various example embodiments is to generate increased number of test patterns in form of the ‘derived test patterns’ from already available test patterns of the ‘base test patterns’.

The ‘derived test patterns’ can be generated from the ‘base test patterns’ in various example embodiments. It should be understood that the ‘derived test patterns’ are additional test patterns that are temporarily generated from the ‘base test patterns’ for the purposes of performing the scan test of one or more digital circuits (e.g., digital circuits 120 and 125) of the circuit array 115, so as to increase the fault coverage during self-test of the one or more digital circuits. Various example embodiments of generation of the ‘derived test patterns’ are hereinafter presented; however, these example embodiments should not be considered limiting to the scope of the present disclosure.

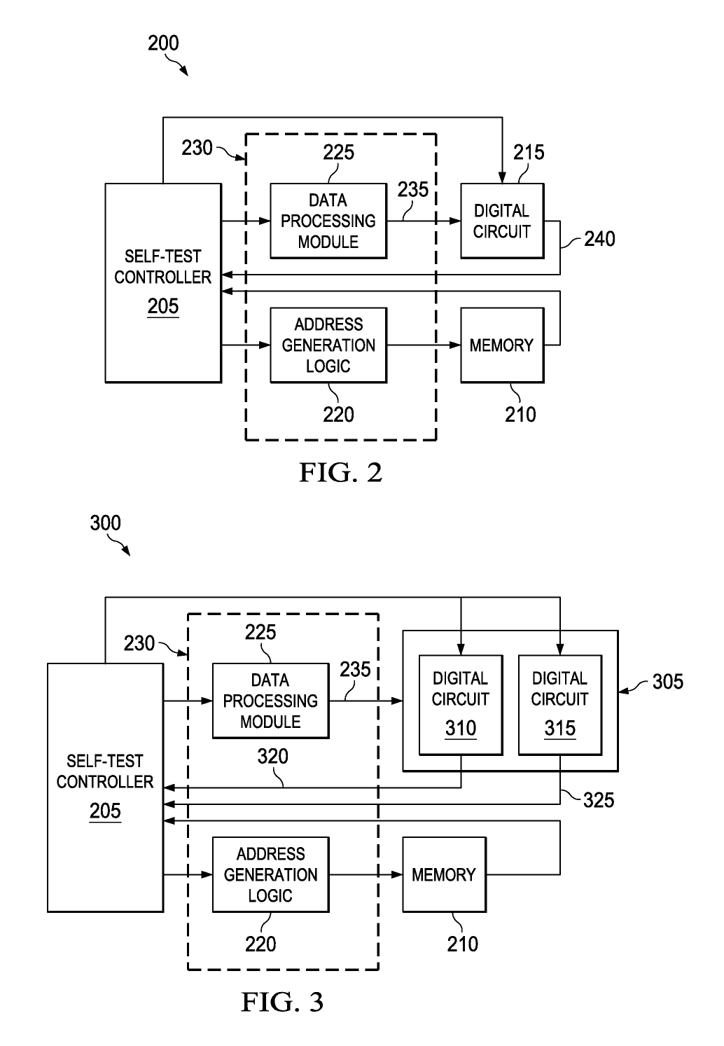

In one example embodiment of generation of ‘derived test patterns’, the ‘base test patterns’ are accessed in different manners to generate the ‘derived test patterns’. For instance, typically, the ‘base test patterns’ are accessed in one or more predefined access orders (e.g., a first access order A1) from the memory 110. A non-exhaustive example of a predefined access order, for example, the first access order A1 may be a sequential order from 0^{th} location to N^{th} location in the memory 110. The self-test controller 105 is also configured to access test patterns from the ‘base test patterns’ in access orders that are different from the predefined access orders. Accordingly, when the test patterns of the ‘base test patterns’ are accessed in sequences that are different than the predefined access orders, the accessed test patterns of the ‘base test patterns’ can be as an example of the ‘derived test patterns’. Hence, in this example embodiment, the ‘derived test patterns’ are generated merely by accessing the test patterns from the ‘base test patterns’ differently than the predefined access orders of the ‘base test patterns’. This example embodiment is further described with reference to FIG. 2.

In another example embodiment of generation of the ‘derived test patterns’, at least one data processing operation can be performed on the ‘base test patterns’ to generate the ‘derived test patterns’. Examples of the data processing operation include, but are not limited to, logical operation, arithmetic operation, shift operation, mask operation, and one or more combinations thereof. Examples of the logical operation include, but are not limited to, logical AND operation, logical OR operation, logical NAND operation, logical NOR operation, logical XOR operation, logical XNOR within or across the test patterns of the ‘base test patterns’, and shift operation, inversion operation on individual test patterns of the ‘base test patterns’. Examples of the arithmetic operation include, but are not limited to, addition, subtraction, multiplication, division, union, intersection, composition, and other unary and binary operations between or across the test patterns of the ‘base test patterns’.

In another example embodiment of generation of the ‘derived test patterns’, a combination of steps involving 1) accessing the ‘base test patterns’ in access orders different from the predefined access orders, and 2) performing ‘data processing operations’ on the one or more test patterns of the ‘base test patterns’, can be carried out to generate the ‘derived test patterns’. For instance, in a non-limiting example, a combination of 1) half of the test patterns of the ‘base test patterns’ accessed differently than the predefined access orders, and 2) test patterns generated from the data processing operation performed on other half test patterns of the ‘base test patterns’, can be used to generate the ‘derived test patterns’.

In another example embodiment of generation of the ‘derived test patterns’, a set of intermediate derived test patterns (hereinafter ‘intermediate derived test patterns’) are obtained by accessing the test patterns from the ‘base test patterns’ differently than the predefined access orders, and thereafter, ‘data processing operation’ can be performed on the ‘intermediate derived test patterns’ to generate the ‘derived test patterns’. In an example, more than one data processing operation may be performed on the ‘intermediate derived test patterns’ to generate the ‘derived test patterns’. As such, it should be understood that any combination of differently accessing the ‘base test patterns’ and thereafter performing the one or more data processing operation, can be utilized to generate the ‘derived test patterns’.

In another example embodiment of generation of the ‘derived test patterns’, one or more control bits can be used for generating the ‘derived test patterns’ from the ‘base test patterns’. In one form, the control bits can be stored in form of registers or memory locations in the memory 110, or any other memory accessible to the self-test controller 105. In an example, the control bits may be in form of ‘B1B2B3’ stored in a memory location, and based on one or more logic states of the control bits, particular way of generation of the ‘derived test patterns’ may be selected. For example, if the logic state of the ‘B1B2B3’ is ‘010’, logical NOT operation may be performed on the ‘base test patterns’, if the state of the ‘B1B2B3’ is ‘101’, the ‘derived test patterns’ can include a combination of: 1) half of the test patterns of the ‘base test patterns’, and 2) results of at least one data processing operation on the other half test patterns of the ‘base test patterns’. Similarly, various ways of generation of the ‘derived test patterns’ can be programmed corresponding to states of the control bits. It should be understood that the control bits can be used with the ‘base test patterns’ or the ‘intermediate derived test patterns’, individually or together, in any manner, to generate the ‘derived test patterns’.

In an example embodiment, the self-test controller 105 applies the set of test patterns (the ‘base test patterns’ and/or the ‘derived test patterns’) for the scan testing of the digital circuit 120 to generate scan outputs (or test response signatures) from the digital circuit 120 based on the scan test of the digital circuit 120. In an example, the set of test patterns from the ‘base test patterns’ and the ‘derived test patterns’ are provided in form of scan inputs to the digital circuit 120, for each test cycle. For instance, the set of test patterns are applied to the decompressor of the digital circuit 120, and the decompressor decompresses the set of test patterns into scan inputs. The scan inputs are further applied to the plurality of scan chains for the scan testing of the digital circuit 120. The compactor of the digital circuit 120 receives outputs of the plurality of scan chains and compacts the outputs into scan outputs. In an example embodiment, the scan outputs are provided in form of test response signatures. However, the scan outputs may not necessarily be in form of the test response signatures, and it can be in other suitable forms of scan outputs. The self-test controller 105 further compares the test response signatures with reference signatures corresponding to the digital circuit 120 for fault detection in the digital circuit 120. In embodiments where the scan outputs are not in form of the test response signatures, the scan outputs received from the digital circuit 120 can be compared with reference scan outputs for fault detection in the digital circuit 120. Similarly, in a recursive manner, remaining test response signatures (or scan outputs) are generated from the digital circuit 120 by applying, at different test cycles, a plurality of combinations of some or all test patterns of the ‘base test patterns’ and the ‘derived test patterns’ for the scan testing of the digital circuit 120. The remaining scan outputs (or test response signatures) generated from the digital circuit 120 are further compared to remaining reference scan outputs (or remaining reference signatures) corresponding to the digital circuit 120. In an example, the reference scan outputs (or the reference signatures) corresponding to the digital circuit 120 are stored in the memory 110. In this manner, by applying the ‘base test patterns’ along with the ‘derived test patterns’, a target fault coverage during the self-test of the digital circuit 120 is achieved.

In an example embodiment, the ‘base test patterns’ used for the scan test of the digital circuit 120 can also be used for the scan test of another digital circuit. In an example embodiment, same test patterns, for example, the ‘base test patterns’ and the ‘derived test patterns’ used for the digital circuit 120 can also be used for performing scan test of the digital circuit 125. In another example embodiment, different base test patterns and correspondingly different ‘derived test patterns’ can be generated for the scan test of the digital circuit 125. In this example embodiment, scan outputs (or test response signatures) are generated from the digital circuit 125, and compared with the reference scan outputs (or reference signatures) corresponding to the digital circuit 125 to determine fault in the digital circuit 125.

In an example embodiment, if the target fault coverage of either the digital circuit 120 or the digital circuit 125 is not achieved, the self-test controller 105 is further configured to apply ‘top-up test patterns’ for the scan test of the digital circuit 120 or the digital circuit 125 to generate top-up test response signatures from the digital circuit 120 or the digital circuit 125, respectively. The ‘top-up test patterns’ are stored in the memory 110. The self-test controller 105 further compares the top-up test response signatures from the digital circuit 120 or the digital circuit 125 with top-up reference signatures corresponding to the digital circuit 120 or the digital circuit 125, respectively to achieve the target fault coverage during the self-test of the digital circuit 120 or the digital circuit 125, respectively. In some example embodiments, same ‘top-up test patterns’ can be used for the scan test of each of the digital circuits 120 and 125. In some example embodiments, there are separate top-up test patterns for the digital circuits 120 and 125. In some example embodiment, the ‘top-up test patterns’ of one digital circuit (e.g., the digital circuit 120) are also used as ‘base test patterns’ for the another digital circuit (e.g., the digital circuit 125) and the ‘derived test patterns’ for the digital circuit 125 can be accordingly generated.

Various example embodiments of the present disclosure providing techniques for self-test of one or more digital circuits, are further described with reference to FIGS. 2 to 4. An example representation of self-test of a single digital circuit is described with reference to FIG. 2.

FIG. 2 is a block diagram of an electronic system 200, in accordance with an example embodiment of the present disclosure. The electronic system 200 includes a self-test controller 205, a memory 210 and a digital circuit 215. The self-test controller 205 along with the memory 210 and other components in the electronic system 200, is configured to perform self-test of the digital circuit 215, and hence the electronic system 200 can be referred to as a ‘self-test system’. The electronic system 200 includes a derived test pattern generator 230. In an example embodiment, the derived test pattern generator 230 is embodied in the self-test controller 205. Alternatively, the derived test pattern generator 230 may be embodied partially as a part of the self-test controller 205, and partially as a separate entity. In FIG. 2, a particular example of the derived test pattern generator 230 is shown for the purposes of description only, and it should not be considered limiting to the scope of various example embodiments of the present disclosure. In this example embodiment, the derived test pattern generator 230 includes an address generation logic 220 and a data processing module 225. The electronic system 200 is shown for representative purposes, and among the shown components, some components can be optional and/or two or more components can be embodied as a single component, or even the electronic system 200 can include additional components than those shown in FIG. 2.

In an example, the self-test controller 205 includes a clock generator, a test pattern generator and a response analyzer. The clock generator is configured to generate a clock signal for each test cycle. The test pattern generator is configured to generate test patterns, for example deterministic patterns for application to the digital circuit 215. The response analyzer is configured to analyze scan outputs or test response signatures received from the digital circuit 215 to determine any fault in the digital circuit 215.

The memory 210 is configured to store ‘base test patterns’, ‘top-up patterns test’, reference scan outputs (or reference signatures) for the scan test of the digital circuit 215. In an example, the memory 210 has a plurality of memory locations, for example row 0 to row M, and the ‘base test patterns’ are stored in memory locations row 0 to row N, where N is smaller than M, and other memory locations can be used to store the ‘top-up test patterns’, and reference scan outputs (the reference signatures). In an embodiment, the digital circuit 215 is configured to include design for test functionality, and the digital circuit 215 can include a decompressor, a plurality of scan chains and a compactor. In one example, the compactor is configured as a multiple-input signature register (MISR). The address generation logic 220 is configured to access the memory 210 in any order, for example, in the predefined access orders, or access orders different than the predefined access orders, based on an address control signal received from the self-test controller 205.

During a test cycle, the self-test controller 205 applies a set of test patterns for the scan testing of the digital circuit 215 to generate test response signatures/scan outputs from the digital circuit 215 based on the scan testing of the digital circuit 215. The set of test patterns can be any combination of the ‘base test patterns’, ‘the top-up test patterns’, and the ‘derived test patterns’, where the ‘derived test patterns’ are derived dynamically from the ‘base test patterns’ and/or the ‘top-up patterns’ in a temporary manner while performing the scan test of the digital circuit 215. As described with reference to FIG. 1, in an example, the ‘derived test patterns’ are generated by performing one or more of: 1) accessing test patterns from the ‘base test patterns’ differently than the predefined access orders, 2) performing data processing operations on the ‘base test patterns’ and/or the ‘top-up test patterns’, 3) applying one or more control bits, and 4) performing data processing operations on the ‘intermediate derived test patterns’.

The derived test pattern generator 230 of the self-test controller 205 is configured to generate the ‘set of derived patterns’ by various techniques, and the ‘set of derived test patterns’ can be used for performing the scan testing of the digital circuit 215 to enhance the fault coverage during self-test of the digital circuit 215. Some of the examples of the generation of the ‘derived test patterns’ are described with reference to FIG. 1 that are non-limiting to the scope of the present disclosure.

In an example, the self-test controller 205 generates the ‘derived test patterns’ by accessing test patterns from the ‘base test patterns’ in various access orders. The self-test controller 205 generates the address control signal at the start of the test cycle and provides the address control signal to the address generation logic 220. In one example, the address control signal is a signal indicative of the predefined access orders or any other access orders of memory locations in the memory 210. The address generation logic 220 receives the address control signal and accordingly generates instructions to access the memory 210. For example, if the address control signal is the signal corresponding to a predefined access order (e.g., a sequential order from row 0 to row N of the memory 210), the ‘base test patterns’ are accessed sequentially from 0^{th} location through N^{th} location in the memory 210 and the ‘base test patterns’ are applied to the digital circuit 215.

In an example, if the address control signal is a signal indicative of an access order other than the predefined access orders, a sequence of test patterns read from the memory 210 form one of the ‘derived test patterns’. Examples of such access orders that are different than the predefined access orders may include, but are not limited to, reverse orders of the predefined access orders, a skip-level order and any random order of accessing the memory 210. For example, if for a given base test pattern, the predefined access order is from 0^{th} location through N^{th} location in the memory 210 (e.g., the first access order A1), a different access order (e.g., the second access order A2) can be a sequential access of the locations starting from the N^{th} location through the 0^{th} location. In another example, the second access order A2 can be a combination of a sequential access of odd locations of the locations starting from the 0^{th} location through the N^{th} location and a sequential access of even locations of the locations starting from the 0^{th} location through the N^{th} location. For example if the second access order A2 is a skip-level order of step 2 and N is 10, the second access order A2 can be a sequence of locations 1, 3, 5, 7, 9 followed by locations 0, 2, 4, 6, 8, 10 to generate the ‘derived test patterns’. In another example, if the second access order A2 is a skip-level order of step 3, a sequence of locations 0, 3, 6, 9 followed by locations 1, 4, 7, 10 followed by locations 2, 5, 8 can be accessed to generate the ‘derived test patterns’. It should be understood that the second access order A2 can be any access order other than the first access order A1 such that accessing the test patterns from the ‘base test patterns’ in the second access order A2 provides one of the ‘derived test patterns’. In an example embodiment, the second access order A2 can be selected based on the control bits stored in the memory 210 or in the self-test controller 205.

The data processing module 225 of the derived test pattern generator 230 is further configured to generate the ‘derived test patterns’. The data processing module 225 is configured to perform data processing operations including, but not limited to, logical operation, arithmetic operation, shift operation, mask operation, and combination thereof on the ‘base test patterns’ or the ‘intermediate derived test patterns’ accessed from the memory 210, to generate the ‘derived test patterns’. For instance, using the address generation logic 220, the self-test controller 205 obtains either the ‘base test patterns’ or the ‘intermediate derived test patterns’, and further the data processing module 225 performs at least one data processing operation to generate the ‘derived test patterns’. Accordingly, it should be noted that a combination of access of the test patterns from the ‘base test patterns’ differently and the data processing operations, can be utilized to generate the ‘derived test patterns’. For instance, the test patterns can be accessed from the ‘base test patterns’ in the second access order A2, and thereafter a data processing operation can be performed on the ‘intermediate derived test patterns’ that are accessed in the second access order A2. In an example, the test patterns are accessed from the ‘base test patterns’ in the reverse order, and an inversion operation can be performed on the test patterns accessed in the reverse order (e.g., the ‘intermediate derived test patterns’) to generate the ‘derived test patterns’. In another example, XOR operation can be performed between patterns of the intermediate derived test patterns (e.g., the test patterns accessed in the second access order A2) to generate the ‘derived test patterns’. In yet another example, both the inversion operation and the XOR operation can be performed on the ‘intermediate derived test patterns’. In yet another example, the ‘intermediate derived test patterns’ can be generated by accessing selected test patterns from the ‘base test patterns’, for example, accessing locations from location 0 to location N-8 of the memory 210 in either the first access order A1 or the second access order (A2), and further a logical operation (e.g., the logical AND operation) may be performed between test patterns of the ‘intermediate derived test patterns’ to generate the ‘derived test patterns’. In yet another example, the ‘intermediate derived test patterns’ can be generated by accessing locations 0 to location N-8 of the memory 210 in either the first access order A1 or the second access order A2, and a logical NOT operation can be performed on the remaining test patterns of the ‘base test patterns’, for example test patterns stored from location N-7 to location N of the memory 210 to generate the ‘derived test patterns’.

It should be understood that in some example embodiments, operations of the data processing module 225 can be controlled by the one or more control bits stored in the memory 210 or in a different device. The data processing module 225 can be configured in a variety of ways, so that it can perform the data processing operations. For example, the data processing module 225 can be configured in form of combinational circuits, logic blocks, arithmetic and logical units, and the like. In some example embodiment, the data processing module 225 can also include one or more software and/or firmware controlled modules in combination with other physical circuit components, so as to perform the functionalities of the data processing module 225.

The data processing module 225 is configured to perform the data processing operation within or across test patterns of the one or more base test patterns and/or the one or more intermediate sets of derived test patterns. For instance, XOR operations may be performed between test patterns of a single set of ‘base test patterns’, or between test patterns of two distinct sets of the ‘base test patterns’, to generate the ‘derived test patterns’.

In an example, the set of test patterns (either the ‘base test patterns’ or the ‘derived test patterns’) are provided as scan inputs in each test cycle. The scan inputs (e.g., see 235) are applied to the digital circuit 215, for example, to the decompressor of the digital circuit 215. The decompressor decompresses the scan input into a set of scan patterns that are further propagated through the plurality of scan chains for the scan testing of the digital circuit 215. In one form, identical scan inputs are fed to different input channels of digital circuit 215, and thereafter the decompressor provides the set of scan patterns to the plurality of scan chains. The compactor of the digital circuit 215 receives outputs of the plurality of scan chains and compacts the scan chain outputs into scan outputs (e.g., see 240). In one example, the scan output may be in form of a test response signature. The self-test controller 205 further compares the test response signature with a corresponding reference signature corresponding to the digital circuit 215 for fault detection in the digital circuit 215. Similarly, in an iterative manner, remaining test response signatures are generated from the digital circuit 215 by applying, at different test cycles, some or all of the set of test patterns (obtained from the ‘base test patterns’ and/or the ‘derived test patterns’) for the scan testing of the digital circuit 215. The remaining test response signatures generated from the digital circuit 215 are further compared to remaining reference signatures corresponding to the digital circuit 215. In an example, the reference test response signatures corresponding to the digital circuit 215 are stored in the memory 210 and subsequently accessed by the self-test controller 205. A target fault coverage during self-test of the digital circuit 215 is thereby achieved.

In an example embodiment, the ‘derived test patterns’ are also obtained by using one or more modes of applications of scan inputs to the digital circuit 215. Examples of the one or more modes include, but are not limited to, a broadcast mode, an XOR mode, a re-seeding mode and a shared mode. The self-test controller 205 is configured to select the one or more modes of applications of the scan inputs based on one or more control bits. For example, states of the one or more control bits may be set in accordance with timing of test phase, number of the ‘base test patterns’ available in the memory 210, available modes of scan test, target fault-coverage, a current fault-coverage obtained during the scan test, and the self-test controller 205 can suitably select the one or more modes of applications of the scan inputs based on the states of the one or more control bits.

In an example of the broadcast mode, individual bits of the base test patterns are provided to different inputs of the digital circuit 215, for example, to the decompressor of the digital circuit 215. In the XOR mode, exclusive-OR (XOR)-based logic can be applied to the bits within the test patterns of the ‘base test patterns’ and/or the ‘intermediate derived test patterns’ to generate the ‘derived test patterns’ before applying to the inputs of the digital circuit 215. It should be noted that data manipulation functions other than the exclusive-OR (XOR) can also be used to generate the ‘derived test patterns’. In the re-seeding mode, individual bits of the ‘base test patterns’, ‘intermediate derived test patterns’ and/or ‘derived test patterns’ are modified using the one or more control bits before being applied to the inputs (e.g., inputs of the decompressor) of the digital circuit 215. In an example of the re-seeding mode, the individual bits can also be used as control bits themselves. It should be understood that the re-seeding mode enables changes in content of the ‘base test patterns’ and/or the ‘derived test patterns’ using the one or more control bits, which in turn allows generation of a different set of derived patterns. In the shared mode, a sub-set of bits of the test patterns applied to the inputs of the digital circuit 215 can again be used as the ‘derived test patterns’ for a current test phase of the digital circuit 215 or for another digital circuit. The test patterns applied at the inputs of the digital circuit 215 can also be applied to inputs of the another digital circuit.

In some example embodiments, if the target fault coverage during the self-test of the digital circuit 215 is not achieved, the self-test controller 205 is further configured to additionally apply the ‘top-up test patterns’ for the scan testing of the digital circuit 215 to generate top-up test response signatures (or other forms of scan outputs) from the digital circuit 215. In these example embodiments, the ‘top-up test patterns’ and top-up reference signatures/reference top-up scan outputs are stored in the memory 210 and are accessed by the self-test controller 205. The self-test controller 205 further compares the top-up test response signatures received from the digital circuit 215 with top-up reference signatures/reference top-up scan outputs corresponding to the digital circuit 215 to achieve the target fault coverage during the self-test of the digital circuit 215.

An example embodiment of self-test of multiple digital circuits is described with reference to FIG. 3.

FIG. 3 is a block diagram of an electronic system 300, in accordance with another example embodiment. The electronic system 300 includes the self-test controller 205, the memory 210, and a circuit array 305. The circuit array 305 includes one or more digital circuits, for example a digital circuit 310 and a digital circuit 315. The electronic system 300 includes the derived test pattern generator 230 including the address generation logic 220 and the data processing module 225. In an example embodiment, the derived test pattern generator 230 can be embodied partially or entirely as part of the self-test controller 205. The electronic system 300 is shown for representative purposes, and among the shown components, some components can be optional and/or two or more components can be embodied as a single component, or even the electronic system 300 can include additional components than those shown in FIG. 3.

In an example, the self-test controller 205 along with the derived test pattern generator 230 and content of the memory 210, is configured to perform scan testing of the digital circuits 310 and 315 so as to achieve desired target coverages during self-test of the digital circuits 310 and 315, respectively. The memory 210 is configured to store the ‘base test patterns’, the ‘top-up test patterns’ and one or more reference signatures/reference scan outputs for scan testing of the digital circuits 310 and/or 315 in the circuit array 305. In an example embodiment, the memory 210 is also configured to store one or more control bits for the generation of the ‘derived test patterns’. The memory 210 can include a plurality of memory locations, for example starting from 0^{th} location to N^{th} location (e.g., in form of rows 0 to M). In one example, the ‘base test patterns’ are stored in memory locations starting from 0^{th} location to N^{th} location (M is greater than N), and other memory locations can be used to store the reference test response signatures/reference scan outputs and the ‘top-up test patterns’ and one or more control bits. Each of the digital circuits 310 or 315 can include a decompressor, a plurality of scan chains, and a compactor. In one example, the compactor is configured as a multiple-input signature register (MISR). The address generation logic 220 is configured to facilitate in accessing the memory 210 in predefined access orders for accessing the ‘base test patterns’, and in other access orders for generating the ‘derived test patterns’, based on an address control signal received from the self-test controller 205.

In an example embodiment, the memory 210 may have two separate memory blocks M1 and M2, each dedicated for the digital circuits 310 and 315, respectively. In the memory block M1, base test patterns (also referred to as ‘BP1’) and top-up test patterns (also referred to as ‘TP1’) are stored for the scan test of the digital circuit 310; and in the memory block M2, base test patterns (also referred to as ‘BP2’) and top-up test patterns (also referred to as ‘TP2’) are stored for the scan test of the digital circuit 315. In some example embodiments, the BP1 and BP2 may be common for both the digital circuits 310 and 315. The memory 210 can also include one or more control bits for the generation of the derived test patterns (‘DP1’ and ‘DP2’) for the digital circuits 310 and 315. In another example embodiment, the memory 210 may include the ‘base test patterns’ and the ‘top-up test patterns’ that are used for generating the ‘derived test patterns’ for both the digital circuits 310 and 315. In an example, all test patterns of the ‘base test patterns’ may be used for the digital circuit 310, and some test patterns of the ‘base test patterns’ may be shared test patterns that can also be used for the digital circuit 315.

In some example embodiments, if a desired fault coverage of scan test is not achieved for a particular digital circuit (e.g., the digital circuit 315), the self-test controller 205 is further configured to use the ‘base test patterns’ and/or the ‘top-up test patterns’ of the other digital circuit (e.g., the digital circuit 310). For instance, in example 1, the ‘DP2’ for the digital circuit 315 can be generated from the ‘BP1’, the ‘BP2’, the ‘TP1’ and the ‘TP2’ based on using at least one of different access orders, control bits, or data processing operations. In example 2, the ‘DP2’ can be generated from the ‘BP1’ and ‘TP1’ of the digital circuit 310 based on using at least one of different access orders, control bits, or data processing operations. In example 3, the ‘DP2’ can be generated only from the ‘BP1’ of the digital circuit 310. In example 4, the ‘DP2 can be generated from only the ‘TP1’ of the digital circuit 310. In example 5, a combination of test patterns used in examples 1 to 4 can be used for generating the ‘DP2’ of the digital circuit 315. Further, it should be noted that BP1-BP2, DP1-DP2, TP1-TP2 generated for the digital circuits 310 and 315 can be reused interchangeably for the scan test of both the digital circuits 310 and 315. Other examples of generation of the ‘derived test patterns’ are already described with reference to FIGS. 1 and 2, and those examples are also applicable for generating the ‘DP1’ and the ‘DP2’ for the digital circuits 310 and 315, respectively.

In an example method, during a test cycle, the self-test controller 205 applies the set of test patterns (e.g., the BP1, TP1, DP1 and BP2, TP2, DP2) in form of scan inputs (e.g., see 235) for the scan testing of the digital circuits 310 and 315. The test response signatures/the scan outputs received from the digital circuit 310 (e.g., see 320) and from the digital circuit 315 (e.g., see 325) are compared by the self-test controller 205 against the stored reference test response signatures/reference scan outputs to determine faults in the digital circuits 310 and 315, respectively.

In an example embodiment, scan outputs of one digital circuit can also be used as ‘derived test patterns’ for the other digital circuit. For instance, the scan outputs of the digital circuit 310 can be used as the ‘DP2’ for the digital circuit 315. In an example embodiment, the scan outputs of the digital circuit 310 alone, or in combination with other test patterns, for example, BP1, BP2, TP1, TP2 can be used for generating the ‘DP2’ for the digital circuit 315. Similarly, the scan outputs of the digital circuit 315 can also be used as the DP1 for the digital circuit 310. Further, the generation of the derived test patterns ‘DP1’ and the ‘DP2’ are iterative processes, and each process can make use of any of the various ways in which the ‘DP1’ and the ‘DP2’ may be derived using the base test patterns ‘BP1’ and ‘BP2’ and the top-up test patterns ‘TP1’ and TP2) and/or using the control bits.

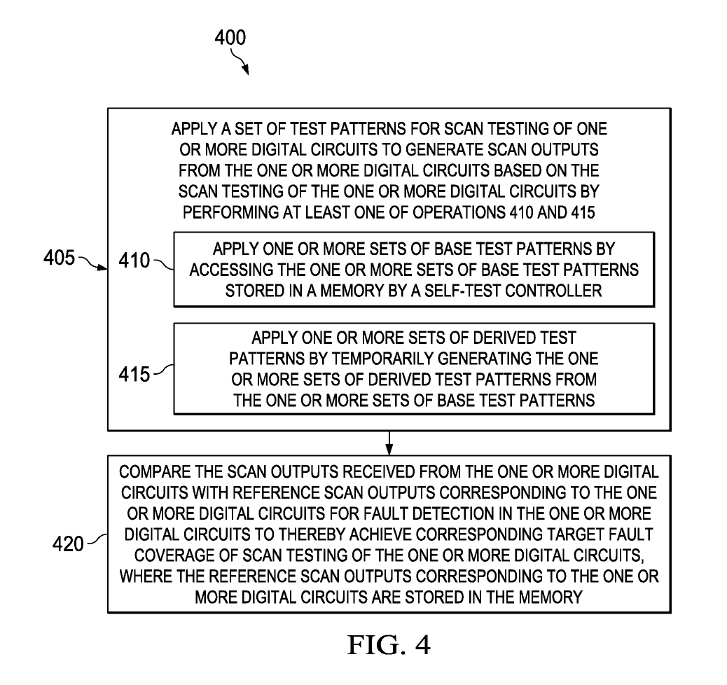

It should be noted that FIGS. 2 and 3 are provided for representation of example embodiments only, and should not be considered limiting to the scope of the example embodiments. Example methods of performing self-test of digital circuits are explained further with reference to FIG. 4. It will be noted that for the description of the methods in FIG. 4, various references will be made to the FIGS. 1 to 3 for explaining one or more embodiments of the method of performing the self-test of the digital circuits.

FIG. 4 illustrates a flowchart of an example method 400 of performing self-test of one or more digital circuits, for example digital circuit 310 and 315 of FIG. 3, according to an example embodiment. The digital circuits can be part of an electronic system, for example the electronic systems 200 or 300, where the electronic system includes a self-test controller (e.g., the self-test controller 205) and a memory (e.g., the memory 210 of FIG. 2) along with other components for performing self-test of the digital circuits.

At 405, the method 400 includes applying a set of test patterns for scan testing of a digital circuit to generate scan outputs from the digital circuit based on the scan testing of the digital circuit. The operation of the block 405 is performed by operations of the blocks 410 and 415. The set of test patterns includes at least one of one or more sets of base test patterns (hereinafter ‘base test patterns’) and one or more sets of derived test patterns (hereinafter ‘derived test patterns’). The ‘derived test patterns’ are test patterns that are temporarily generated from the ‘base test patterns’.

At 410, for applying the ‘base test patterns’ as the set of test patterns, the ‘base test patterns’ are accessed from the memory by the self-test controller. The ‘base test patterns’ are stored in the memory accessible to the self-test controller. In an example, the self-test controller generates an address control signal at start of a test cycle and provides the address control signal to an address generation logic (e.g., the address generation logic 220 of FIG. 2). In one example, the address control signal is a signal indicative of a memory address. The address generation logic accesses the ‘base test patterns’ from the memory based on the address control signal for the scan testing of the digital circuit. The ‘base test patterns’ are accessed in one or more predefined access orders, for example, a first access order A1 from the memory. In a non-limiting example, the first access order A1 is a sequential order from location 0 to location N of the memory. In an embodiment, if the ‘base test patterns’ are stored in locations starting from 0^{th} location through N^{th} location in the memory, the first access order A1 is a sequential access of the locations starting from the 0^{th} location through the N^{th} location.

At 415, for applying the ‘derived test patterns’ as the set of test patterns, the method 400 includes generating the ‘derived test patterns’ from the ‘base test patterns’. Several techniques of generating the ‘derived test patterns’ are described with reference to FIGS. 1 to 3, and those techniques are not described again herein for the sake of brevity. For instance, in an example, the ‘derived test patterns’ are generated by accessing test patterns from the ‘base test patterns’ in access orders different from the one or more predefined access orders from the memory. In another example, the ‘derived test patterns’ are generated by performing at least one data processing operation on the ‘base test patterns’, where examples of the at least one data processing operation includes a logical operation, an arithmetic operation, or a combination thereof. The data processing operation can be performed within test patterns or across test patterns of the ‘base test patterns’. In another example, the ‘derived test patterns’ are generated by first generating an ‘intermediate derived test patterns’ by accessing test patterns from the ‘base test patterns’ in an access order different from the one or more predefined access orders from the memory, and thereafter performing a data processing operation on the ‘intermediate derived test patterns’ to generate the ‘derived test patterns’. In another example, the ‘derived test patterns’ are generated based on the one or more control bits. In this example, based on states of the one or more control bits, an access order for accessing the test patterns from the ‘base test patterns’ and a suitable data processing operation can be selected for generating the ‘derived test patterns’.

At 420, the method 400 includes comparing the scan outputs received from the digital circuit with reference scan outputs corresponding to the digital circuit for fault detection in the digital circuit. The reference scan outputs corresponding to the digital circuit are stored in the memory. In an example, if the target fault coverage of the digital circuit is not achieved, one or more sets of top-up test patterns (hereinafter ‘top-up test patterns’) can be additionally applied for the scan testing of the digital circuit. The ‘top-up test patterns’ are stored in the memory and are accessed by the self-test controller, and corresponding reference scan outputs are also stored in the memory. The scan outputs received from the digital circuit are compared with the reference scan outputs corresponding to the digital circuit to achieve the target fault coverage during self-test of the digital circuit.

It should be understood that the operations of the method 400 are iterative, and the set of test patterns are applied for the scan test of the digital circuit until the target fault coverage is obtained during the self-test of the digital circuit. Various techniques and their combinations of generation of the ‘derived test patterns’ are performed to apply increased number of test patterns for the scan test of the one or more digital circuits (e.g., digital circuit 1 and digital circuit 2), as compared to only stored test patterns in the memory. In an embodiment, the ‘base test patterns’ and the ‘derived test patterns’ corresponding to a digital circuit (e.g., the digital circuit 1) can be further applied, at different or same test cycles, for scan testing of another digital circuit (e.g., digital circuit 2) to generate scan outputs from the digital circuit 2. The scan outputs are generated from the digital circuit 2 by applying one or more combinations of some or all test patterns of the ‘base test patterns’ and the ‘derived test patterns’ corresponding to the digital circuit 1, for scan testing of the digital circuit 2. The scan outputs (or test response signatures) generated from the digital circuit 2 are further compared to reference scan outputs (or reference signatures) corresponding to the digital circuit 2. The reference scan outputs corresponding to the digital circuit 2 are already stored in the memory. Accordingly, a target fault coverage during self-test of the digital circuit 2 is thereby achieved. In an embodiment, if the target fault coverage of the digital circuit 2 is not achieved, ‘top-up test patterns’ can be applied for scan testing of the digital circuit 2 to generate top-up scan outputs (or test response signatures) from the digital circuit 2. The ‘top-up test patterns’ are stored in the memory and are subsequently accessed by the self-test controller. The top-up scan outputs (or test response signatures) from the digital circuit 2 are compared with top-up reference scan outputs (or reference signatures) corresponding to the digital circuit 2 to achieve the target fault coverage during self-test of the digital circuit 2.

It should be noted that the ‘base test patterns’, the ‘top-up test patterns’ and the ‘derived test patterns’ may be applied to the digital circuit 1 and/or the digital circuit 2 in any order. For instance, in an example, the scan testing of the digital circuits 1 and 2 may be performed based on applying the ‘base test patterns’, followed by applying the ‘derived test patterns’, and thereafter applying the ‘top-up test patterns’, if the target fault coverages during the self-test of the digital circuits 1 and 2 are not achieved. In another example, the ‘derived test patterns’ may be derived dynamically from the stored ‘base test patterns’ and applied for the scan testing of the digital circuits 1 and 2, and thereafter the ‘base test patterns’ are applied for the scan test of the digital circuits 1 and 2. In some example, the control bits are used to apply the set of test patterns from the ‘derived test patterns’, the ‘base test patterns’, and the ‘top-up test patterns’ in any dynamically selected order. Further, it should be appreciated that due to non-storage of the ‘derived test patterns’, there is no need of any additional memory space in the memory.

It should be appreciated that various example embodiments offer significant improvement in target fault coverage of the digital circuits by applying the ‘derived test patterns’ for scan testing of the digital circuits. Such improvements in the target fault coverage of the digital circuits are further described by comparing experimental results of an example embodiment of the present disclosure with some example scenarios that are in existence, and such comparisons are described with reference to Tables 1 to 3. For instance, Table 1 relates to a scenario 1, where the ‘base test patterns’ are applied to the digital circuit 1 in a broadcast mode (existing scenario) and the digital circuit 1 has a standalone fault coverage of 90.42%. When the test patterns are accessed from the ‘based test patterns’ in reverse order to generate the derived test pattern and applied to the digital circuit 1 in the broadcast mode, the fault coverage is improved to 91.80% as compared to existing fault coverage of 90.42%. Similarly, inversion operation is applied to the ‘base test patterns’ in the broadcast mode to obtain the fault coverage of 91.95%; test patterns are accessed in the reverse order from the ‘base test patterns’ and the inversion operation is applied to such test patterns in the broadcast mode to obtain the fault coverage of 92.68%; the base test patterns are accessed and applied to the digital circuit 1 in the XOR mode to obtain the fault coverage of 93.46%; the test patterns of the ‘base test patterns’ are accessed in the reverse order and applied to the digital circuit 1 in the XOR mode to obtain the fault coverage of 93.67%; the inversion operation is applied to the ‘base test patterns’ in the XOR mode to obtain the fault coverage of 94.13%; and the test patterns of the ‘base test patterns’ are accessed in the reverse order and the inversion operation is applied to such test patterns in the XOR mode to obtain the fault coverage of 94.39%. Hence, as illustrated in the Table 1, the ‘derived test patterns’ are applied to the digital circuit 1 to further improve the fault coverage from the existing fault coverage of 90.42% to 94.39% without additional memory overhead.

TABLE 1

| | Fault |
|---|---|
| Experiments | Coverage |
| 1. Digital circuit 1: Base test patterns in broadcast mode | 90.42% |
| 2. Digital circuit 1: Base test patterns in reverse order in | 91.80% |
| broadcast mode | |
| 3. Digital circuit 1: Base test patterns with inversion in | 91.95% |
| broadcast mode | |
| 4. Digital circuit 1: Base test patterns in reverse order with | 92.68% |
| inversion in broadcast mode | |
| 5. Digital circuit 1: Base test patterns in XOR mode | 93.46% |
| 6. Digital circuit 1: Base test patterns in reverse order and in | 93.67% |
| XOR mode | |
| 7. Digital circuit 1: Base test patterns with inversion in XOR | 94.13% |
| mode | |
| 8. Digital circuit 1: Base test patterns in reverse order with | 94.39% |
| inversion and in XOR mode | |

In another example, Table 2 relates to a scenario 2, where the test patterns applied to the digital circuit 1 are re-applied to another digital circuit, for example digital circuit 2, and different values of fault coverage achieved during the self-test of the digital circuit 2 are tabulated. For instance, the ‘base test patterns’ applied to the digital circuit 1 in the broadcast mode are re-applied or re-simulated on digital circuit 2 to obtain the fault coverage of 75.85%. The derived set patterns (e.g., test patterns of the ‘base test patterns’ that are accessed in the reverse order and applied to the digital circuit 1 in the broadcast mode) for the digital circuit 1 are re-applied to digital circuit 2 to obtain the fault coverage of 79.10%. Similarly, the ‘derived test patterns’ (e.g., inversion operation applied to the ‘base test patterns’ in the broadcast mode for digital circuit 1) for the digital circuit 1 is re-applied to the digital circuit 2 to obtain the fault coverage of 80.82%; the ‘derived test patterns’ (e.g., test patterns of the ‘base test patterns’ accessed in the reverse order and the inversion operation applied to such test patterns in the broadcast mode for digital circuit 1) is re-applied to the digital circuit 2 to obtain the fault coverage of 81.58%; the ‘derived test patterns’ (e.g., the ‘base test patterns accessed and applied to the digital circuit 1 in the XOR mode) is re-applied to the digital circuit 2 to obtain the fault coverage of 82.44%; the ‘derived test patterns’ (e.g., the test patterns of the ‘base test patterns’ accessed in the reverse order and applied to the digital circuit 1 in the XOR mode) is re-applied to the digital circuit 2 to obtain the fault coverage of 82.84%; the ‘derived test patterns’ (e.g., the inversion operation applied to the ‘base test patterns’ in the XOR mode for digital circuit 1) is re-applied to the digital circuit 2 to obtain the fault coverage of 83.02%; and the ‘derived test patterns’ (e.g., the test patterns of the ‘base test patterns’ being accessed in the reverse order and the inversion operation applied to such test patterns in the XOR mode for digital circuit 1) is re-applied to the digital circuit 2 to obtain the fault coverage of 83.16%. If the target fault coverage is above 90%, the fault coverage determined for the digital circuit 2 can be improved by applying ‘top-up test patterns’ stored in the memory. Hence, as illustrated in the Table 2, the test patterns applied to the digital circuit 1 are also applied to the digital circuit 2 and such technique further reduces the memory requirements.

TABLE 2

| | Fault |
|---|---|
| Experiments | Coverage |
| Base test patterns of digital circuit 1 re-simulated on digital | 75.85% |
| circuit 2 in broadcast mode | |
| Base test patterns of digital circuit 1 re-simulated on digital | 79.10% |
| circuit 2 in reverse order in broadcast mode | |
| Base test patterns of digital circuit 1 re-simulated on digital | 80.82% |
| circuit 2 with inversion in broadcast mode | |
| Base test patterns of digital circuit 1 re-simulated on digital | 81.58% |
| circuit 2 in reverse order with inversion in broadcast mode | |
| Base test patterns of digital circuit 1 re-simulated on digital | 82.44% |
| circuit 2 in XOR mode | |
| Base test patterns of digital circuit 1 re-simulated on digital | 82.84% |
| circuit 2 in XOR mode in reverse order | |
| Base test patterns of digital circuit 1 re-simulated on digital | 83.02% |
| circuit 2 in XOR mode with inversion | |
| Base test patterns of digital circuit 1 re-simulated on digital | 83.16% |
| circuit 2 in XOR mode in reverse order with inversion | |

The savings in memory requirements are illustrated in Table 3 by comparing experimental results of an example embodiment of the present disclosure with an existing scenario that is not in accordance with the present disclosure. In a typical example, a pattern count of the test patterns applied to the digital circuit 1 for obtaining 90% target fault coverage is 512 with a chain length of 256, and a pattern count of the test patterns applied to the digital circuit 2 for obtaining 90% target fault coverage is 256 with a chain length of 256. Hence, in the existing scenario (that is not in accordance with the present disclosure), the total pattern count for the digital circuits 1 and 2 is 768 and the total used memory (i.e., total bits) is 196608 bits. In the table 3, the ‘total pattern count’ column refers to a sum of the pattern count for the digital circuits 1 and the pattern count for the digital circuit 2, and the ‘total bits’ column refers to a number of bits (for a single scan input) that need to be stored for the test patterns for the digital circuits 1 and 2. As per the experimental results corresponding to an example embodiment of the present disclosure, a pattern count of the test patterns applied to the digital circuit 1 (for obtaining 90% target fault coverage) and to the digital circuit 2 (for obtaining 83.16% target fault coverage) is 512 with a chain length of 256. Further, a pattern count of additional test patterns (e.g., top-up test patterns) applied to the digital circuit 2 for improving the target fault coverage from 83.16% to 90% is 128 with a chain length of 256. Hence, in accordance with the example embodiment of the present disclosure, the total pattern count for the digital circuits 1 and 2 is 640 and the total used memory is 163840 bits. Accordingly, savings in the memory bits in accordance with the present disclosure as compared to the existing scenario (see, ‘Savings in memory bits’ column) is 32768, and savings in number of rows (32 bits wide) of a read only memory (ROM) in accordance with the present disclosure as compared to the existing scenario (see, ‘Savings in number of ROM rows (32 bits wide)’ column) is 1024 rows.

TABLE 3

| | | | | | | Savings in |
|---|---|---|---|---|---|---|
| | | | | | | number of |
| | | Total | | | Savings in | ROM rows |
| | Pattern | pattern | Chain | Total | memory | (32 bits |
| Experiments | count | count | length | bits | bits | wide) |
| Digital circuit 1 | 512 | | 256 | | | |
| standalone test pattern | | | | | | |
| count for 90% fault | | | | | | |
| coverage | | | | | | |
| As per an existing | 256 | 768 | 256 | 196608 | | |
| scenario: Digital circuit 2 | | | | | | |
| standalone pattern count | | | | | | |
| for 90% fault coverage | | | | | | |
| As per the present | 128 | 640 | 256 | 163840 | 32768 | 1024 |
| disclosure: Pattern count | | | | | | |
| for improving fault | | | | | | |
| coverage in digital | | | | | | |
| circuit 2 from 83.16% to | | | | | | |
| 90% | | | | | | |

Without in any way limiting the scope, interpretation, or application of the claims appearing below, advantages of one or more of the example embodiments disclosed herein include, to provide self-test systems for performing self-test of digital circuits with reduced memory requirement. Various example embodiments are capable of increasing a target fault coverage during scan test by enhancing number of test patterns applied on the digital circuits. For example, ‘derived test patterns’ are generated from the existing ‘base test patterns’ and the ‘top-up test patterns’. Various techniques, such as accessing the test patterns from the ‘base test patterns’ in multiple ways, performing data processing operations, utilizing control bits, using test patterns of the ‘base test patterns’ and/or ‘top-up test patterns’ and/or ‘intermediate derived test patterns’ in one or more modes (e.g., broadcast mode, XOR mode, re-seeding mode and shared mode) and the ‘top-up test patterns’, are employed to generate the additional test patterns that can be used for the scan testing of the digital circuits. The electronic system has minimal internal overheads in terms of memory and area in using various pattern application techniques described herein, and in reusing test patterns generated for one digital circuit for the scan testing of another digital circuit in the electronic system.

Although the present disclosure has been described with reference to specific example embodiments, it is noted that various modifications and changes can be made to these embodiments without departing from the broad spirit and scope of the present disclosure. For example, the various circuits, etc., described herein can be enabled and operated using hardware circuitry (e.g., complementary metal oxide semiconductor (CMOS) based logic circuitry), firmware, software and/or any combination of hardware, firmware, and/or software (e.g., embodied in a machine-readable medium). For example, the various electrical structures and methods can be embodied using transistors, logic gates, and electrical circuits (e.g., application specific integrated circuit (ASIC) circuitry and/or in Digital Signal Processor (DSP) circuitry).

Particularly, the self-test controllers 105 and 205 may be enabled using software and/or using transistors, logic gates, and electrical circuits (e.g., integrated circuit circuitry, such as, for example, ASIC circuitry). Embodiments of the present disclosure include one or more computer programs stored or otherwise embodied on a computer-readable medium, wherein the computer programs are configured to cause a processor to perform one or more operations, for the method 400. A computer-readable medium storing, embodying, or encoded with a computer program, or similar language, may be embodied as a tangible data storage device storing one or more software programs that are configured to cause a processor to perform one or more operations. Such operations may be, for example, any of the steps or operations described herein. Additionally, a tangible data storage device may be embodied as one or more volatile memory devices, one or more non-volatile memory devices, and/or a combination of one or more volatile memory devices and non-volatile memory devices.

Various embodiments of the present disclosure, as discussed above, can be practiced with steps and/or operations in a different order, and/or with hardware elements in configurations which are different than those which are disclosed. Therefore, although the disclosure has been described based upon these example embodiments, it is noted that certain modifications, variations, and alternative constructions can be apparent and well within the spirit and scope of the disclosure. Although various example embodiments of the present disclosure are described herein in a language specific to structural features and/or methodological acts, the subject matter defined in the appended claims is not necessarily limited to the specific features or acts described above. Rather, the specific features and acts described above are disclosed as example forms of implementing the claims.

What is claimed is:

1. A method of performing self-test of digital circuits, the method comprising:
applying a set of test patterns for scan testing of a digital circuit to generate scan outputs from the digital circuit based on the scan testing of the digital circuit in which applying the set of test patterns includes applying at least one of:
one or more sets of base test patterns, and
one or more sets of derived test patterns,
in which applying the one or more sets of base test patterns includes accessing the one or more sets of base test patterns stored in a memory by a self-test controller, and
in which applying the one or more sets of derived test patterns includes temporarily generating the one or more sets of derived test patterns from the one or more sets of base test patterns; and
comparing the scan outputs received from the digital circuit with reference scan outputs corresponding to the digital circuit for fault detection in the digital circuit, in which the reference scan outputs corresponding to the digital circuit are stored in the memory.

2. The method of claim 1 in which generating the one or more sets of derived test patterns includes accessing test patterns from the one or more sets of base test patterns in one or more access orders different than one or more predefined access orders from the memory, in which the one or more predefined access orders correspond to accessing the one or more sets of base test patterns.

3. The method of claim 1 in which generating the one or more sets of derived test patterns includes performing at least one data processing operation on the one or more sets of base test patterns.

4. The method of claim 3 in which the at least one data processing operation includes at least one of: a logical operation, and an arithmetic operation.

5. The method of claim 1 in which generating the one or more sets of derived test patterns includes:
generating one or more intermediate sets of derived test patterns by accessing one or more test patterns of the one or more sets of base test patterns in one or more access orders different than one or more predefined access orders from the memory; and
performing at least one data processing operation on the one or more intermediate sets of derived test patterns to generate the one or more sets of derived test patterns.

6. The method of claim 1 in which generating the one or more sets of derived test patterns further includes generating the one or more sets of derived test patterns based on one or more control bits.

7. The method of claim 1 in which generating the one or more sets of derived test patterns includes performing at least one of:
accessing test patterns of the one or more sets of base test patterns in one or more access orders different than one or more predefined access orders from the memory, in which the one or more predefined access orders correspond to accessing the one or more sets of base test patterns;
performing at least one data processing operation on the one or more sets of base test patterns; and
generating the one or more sets of derived test patterns based on one or more control bits, in which one or more states of the one or more control bits cause to select an access order for accessing test patterns from the one or more sets of base test patterns and cause to select the at least one data processing operation.

8. The method of claim 1 in which generating the one or more sets of derived test patterns includes using test patterns of the one or more sets of base test patterns in at least one of a broadcast mode, an XOR mode, a re-seeding mode and a shared mode.

9. The method of claim 1 including applying the set of test patterns for scan testing of another digital circuit to generate scan outputs from the another digital circuit, and in which the scan outputs generated from the another digital circuit are compared with reference scan outputs corresponding to the another digital circuit stored in the memory for fault detection in the another digital circuit.

10. The method of claim 9 in which applying the one or more sets of derived test patterns for the scan testing of the another digital circuit includes applying the scan outputs received from the digital circuit as part of the one or more sets of derived test patterns for the scan testing of the another digital circuit.

11. The method of claim 9 in which applying the one or more sets of base test patterns further includes applying one or more sets of top-up test patterns for scan testing of at least one of the digital circuit and the another digital circuit.

12. A self-test system for scan testing of one or more digital circuits, the self-test system comprising:
a memory configured to store one or more sets of base test patterns and one or more reference scan outputs for the scan testing of the one or more digital circuits; and
a self-test controller coupled to the memory, configured to:
apply a set of test patterns for scan testing of a digital circuit of the one or more digital circuits to generate scan outputs from the digital circuit based on the scan testing of the digital circuit, in which applying the set of test patterns includes applying at least one of:
the one or more sets of base test patterns, and
one or more sets of derived test patterns,
in which applying the one or more sets of base test patterns includes accessing the one or more sets of base test patterns stored in the memory, and
in which applying the one or more sets of derived test patterns includes temporarily generating the one or more sets of derived test patterns from the one or more sets of base test patterns; and
compare the scan outputs received from the digital circuit with reference scan outputs of the one or more reference scan outputs corresponding to the digital circuit for fault detection in the digital circuit.

13. The self-test system of claim 12 in which the self-test controller includes an address generation logic for accessing test patterns of the one or more sets of base test patterns in one or more access orders different than one or more predefined access orders from the memory to generate the one or more sets of derived test patterns, in which the one or more predefined access orders correspond to access of the one or more sets of base test patterns from the memory.

14. The self-test system of claim 12 in which the self-test controller includes a data processing module configured to generate the one or more sets of derived test patterns by performing at least one data processing operation on the one or more sets of base test patterns.

15. The self-test system of claim 12 in which the self-test controller is configured to generate the one or more sets of derived test patterns by:
generating one or more intermediate sets of derived test patterns by accessing one or more test patterns of the one or more sets of base test patterns in one or more access orders different than one or more predefined access orders from the memory; and
performing at least one data processing operation on the one or more intermediate sets of derived test patterns to generate the one or more sets of derived test patterns.

16. The self-test system of claim 12 in which the memory is further configured to store one or more control bits, and in which the self-test controller is configured to generate the one or more sets of derived test patterns based on the one or more control bits.

17. The self-test system of claim 12 in which the self-test controller is further configured to generate the one or more sets of derived test patterns by:
accessing test patterns of the one or more sets of base test patterns in one or more access orders different than one or more predefined access orders from the memory, in which the one or more predefined access orders correspond to accessing the one or more sets of base test patterns from the memory by the self-test controller;
performing at least one data processing operation on the one or more sets of base test patterns; and
generating the one or more sets of derived test patterns based on one or more control bits, in which one or more states of the one or more control bits cause to select an access order for accessing test patterns from the one or more sets of base test patterns and cause to select the at least one data processing operation.

18. The self-test system of claim 12 in which the self-test controller is further configured to apply the one or more sets of base test patterns by applying one or more sets of top-up test patterns for scan testing of the one or more digital circuits.

19. The self-test system of claim 18 in which the self-test controller is configured to apply scan outputs of a first digital circuit of the one or more digital circuits as one or more sets of derived test patterns for a second digital circuit of the one or more digital circuits.

20. The self-test system of claim 12 in which the self-test controller is configured to generate the one or more sets of derived test patterns by using test patterns of the one or more sets of base test patterns in at least one of a broadcast mode, an XOR mode, a re-seeding mode and a shared mode.
